(19) United States
(12) Patent Application Publication
(10) Pub. No.: US 2020/0020880 A1
(43) Pub. Date: Jan. 16, 2020

(54) DISPLAY DEVICE

(71) Applicant: Sharp Kabushiki Kaisha, Sakai City, Osaka (JP)

(72) Inventors: Shinsuke SAIDA, Sakai City (JP); Tohru OKABE, Sakai City (JP); Ryosuke GUNJI, Sakai City (JP); Hiroki TANIYAMA, Sakai City (JP); Hiroharu JINMURA, Sakai City (JP); Yoshihiro NAKADA, Sakai City (JP); Akira INOUE, Sakai City (JP)

(21) Appl. No.: 16/496,967

(22) PCT Filed: Mar. 27, 2017
(86) PCT No.: PCT/JP2017/012302

§ 371 Date: Sep. 24, 2019

(51) Int. Cl. H01L 51/52; H01L 27/32; H01L 51/00

(52) U.S. Cl. CPC H01L 51/5253; H01L 51/0097; H01L 27/32

(57) ABSTRACT

A first weir wall and a second weir wall are formed in a frame region, the first weir wall being made of a material of a planarizing film and being formed so as to surround a display region and to overlap a peripheral end of an organic layer of a sealing film, and the second weir wall being made of a material of an edge cover and being formed around the first weir wall so as to overlap an edge of the peripheral end of the organic layer. The first weir wall has a groove formed in its upper surface so as to extend around the display region.

### TECHNICAL FIELD

The present invention relates to display devices.

### BACKGROUND ART

In recent years, self-luminous organic electroluminescence (EL) display devices using an organic EL element have attracted attention as an alternative display device to liquid crystal display devices. In a sealing structure proposed for the organic EL display devices in order to restrain degradation in organic EL element due to contamination with moisture, oxygen, etc., a sealing film covering the organic EL element is a multilayered film of inorganic and organic films.

For example, Patent Document 1 discloses a sealant for an organic EL display element as a material that can be used as the organic layer of the sealing film. This sealant can be easily applied by an inkjet method, is highly curable, and is highly transparent and has high barrier properties when cured.

### CITATION LIST

### Patent Documents

PATENT DOCUMENT 1: Japanese Unexamined Patent Publication No. 2014-225380

### SUMMARY OF THE INVENTION

### Technical Problem

Since formability of an organic layer by an inkjet method is susceptible to the condition of the surface on which the organic layer is to be formed, it is difficult to accurately form the peripheral end (edge) of the organic layer. It is therefore necessary to form a relatively large organic layer to completely cover the underlying inorganic layer. This makes it difficult to implement an organic EL display device with a narrower frame.

The present invention was developed in view of the above circumstances and it is an object of the present invention to implement a display device with a narrower frame by accurately forming the peripheral end of an organic layer of a sealing film.

### Solution to the Problem

In order to achieve the above object, a display device according to the present invention is a display device which includes a base substrate, a plurality of switching elements provided on the base substrate, a planarizing film formed on the plurality of switching elements to flatten a surface having the plurality of switching elements formed thereon, a light emitting element provided on the planarizing film and including an edge cover, and a sealing film formed so as to cover the light emitting element and formed by sequentially stacking a first inorganic layer, an organic layer, and a second inorganic layer, and in which a display region where an image is displayed and a frame region surrounding the display region are defined. The display device is characterized in that a first weir wall and a second weir wall are formed in the frame region, the first weir wall being made of a material of the planarizing film and being formed so as to surround the display region and to overlap a peripheral end of the organic layer, and the second weir wall being made of a material of the edge cover and being formed so as to surround the first weir wall and to overlap an edge of the peripheral end of the organic layer, and the first weir wall has a groove formed in its upper surface so as to extend along a perimeter of the display region.

### Advantages of the Invention

According to the present invention, the first weir wall and the second weir wall are formed in the frame region, and the first weir wall has the groove in its upper surface. The peripheral end of the organic layer of the sealing film can therefore be accurately formed, and a display device with a narrower frame can be implemented.

### BRIEF DESCRIPTION OF THE DRAWINGS

FIG. 1 is a plan view showing a schematic configuration of an organic EL display device according to a first embodiment of the present invention.

FIG. 2 is a sectional view showing a schematic configuration of the organic EL display device taken along line II-II in FIG. 1.

FIG. 3 is a sectional view showing a detailed configuration of a display region of the organic EL display device according to the first embodiment of the present invention.

FIG. 4 is a sectional view showing an organic EL layer forming the organic EL display device according to the first embodiment of the present invention.

FIG. 5 is a sectional view showing a detailed configuration of a frame region of the organic EL display device according to the first embodiment of the present invention.

FIG. 6 is a sectional view showing a detailed configuration of a frame region of an organic EL display device according to a second embodiment of the present invention.

FIG. 7 is a plan view showing a schematic configuration of an organic EL display device according to a third embodiment of the present invention.

FIG. 8 is a sectional view showing a detailed configuration of a frame region of the organic EL display device according to the third embodiment of the present invention.

FIG. 9 is a sectional view showing a detailed configuration of a frame region of the organic EL display device according to a fourth embodiment of the present invention.

FIG. 10 is a sectional view illustrating a manufacturing method of the organic EL display device according to the fourth embodiment of the present invention.

FIG. 11 is a sectional view showing a detailed configuration of a frame region of a modification of the organic EL display device according to the fourth embodiment of the present invention.

### DESCRIPTION OF EMBODIMENTS

Embodiments of the present invention will be described in detail with reference to the accompanying drawings. The present invention is not limited to the following embodiments.

### First Embodiment

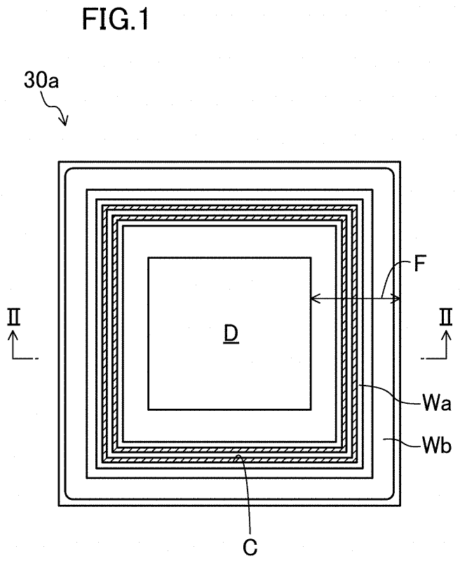

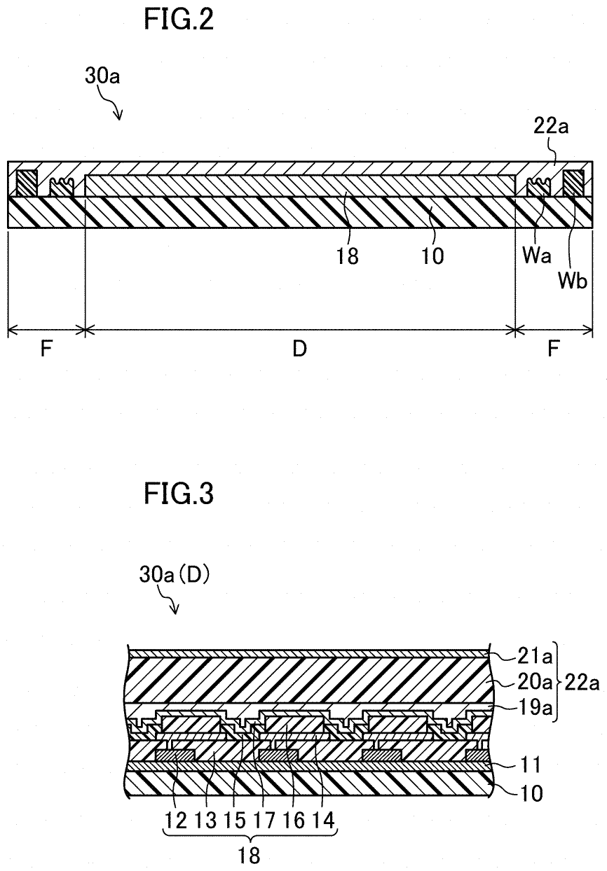

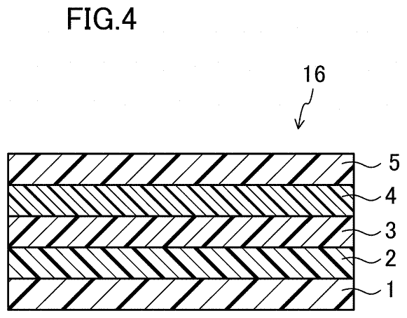

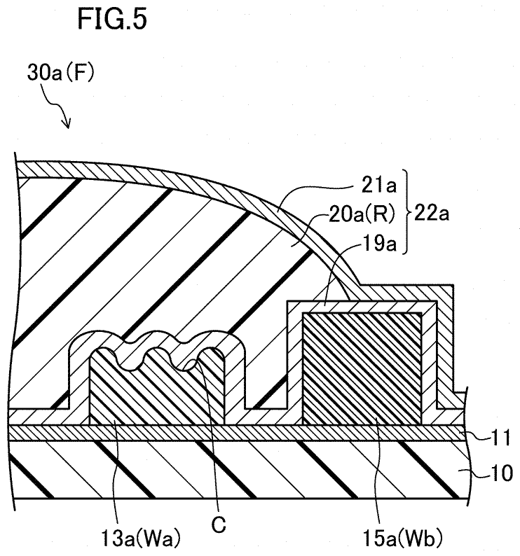

FIGS. 1 to 5 show a first embodiment of a display device according to the present invention. FIG. 1 is a plan view showing a schematic configuration of an organic EL display device 30a of the present embodiment. FIG. 2 is a sectional view showing a schematic configuration of the organic EL display device 30a taken along line II-II in FIG. 1. FIG. 3 is a sectional view showing a detailed configuration of a display region D of the organic EL display device 30a. FIG. 4 is a sectional view showing an organic EL layer 16 forming the organic EL display device 30a. FIG. 5 is a sectional view showing a detailed configuration of a frame region F of the organic EL display device 30a.

As shown in FIGS. 1 to 3, the organic EL display device 30a includes: a base substrate 10; an organic EL element 18 serving as a light emitting element, a first weir wall Wa, and a second weir wall Wb which are formed on the base substrate 10 with a basecoat film 11 interposed therebetween; and a sealing film 22a formed so as to cover the organic EL element 18, the first weir wall Wa, and the second weir wall Wb. As shown in FIG. 1, a rectangular display region D where an image is displayed is defined in the organic EL display device 30a, and a plurality of pixels are arranged in a matrix in the display region D. For example, a sub-pixel for red gradation display, a sub-pixel for green gradation display, and a sub-pixel for blue gradation display are arranged next to each other in each pixel. As shown in FIG. 1, in the organic EL display device 30a, a frame-shaped frame region F is defined around the display region D, and the first weir wall Wa and the second weir wall Wb are formed in the frame region F.

For example, the base substrate 10 is a plastic substrate made of a polyimide resin etc. or a glass substrate.

For example, the basecoat film 11 is an inorganic insulating film such as a silicon oxide film or a silicon nitride film.

As shown in FIG. 2, the organic EL element 18 is provided in the display region D. As shown in FIG. 3, the organic EL element 18 includes a plurality of TFTs 12, a planarizing film 13, a plurality of first electrodes 14, an edge cover 15, a plurality of organic EL layers 16, and a second electrode 17 which are sequentially formed on the basecoat film 11.

The TFTs 12 are switching elements provided for each sub-pixel in the display region D. For example, the TFT 12 includes: an island-shaped semiconductor layer formed on the basecoat film 11; a gate insulating film formed so as to cover the semiconductor layer; a gate electrode formed on the gate insulating film so as to overlap a part of the semiconductor layer; an interlayer insulating film formed so as to cover the gate electrode; and a source electrode and a drain electrode which are formed on the interlayer insulating film so as to be separated from each other. Although the top-gate TFTs 12 are shown in the present embodiment, the TFTs 12 may be bottom-gate TFTs.

As shown in FIG. 3, the planarizing film 13 covers each TFT 12 except for a part of its drain electrode to flatten the surface having the TFTs 12 formed thereon. For example, the planarizing film 13 is made of a colorless transparent organic resin material such as an acrylic resin.

As shown in FIG. 3, the plurality of first electrodes 14 are arranged in a matrix on the planarizing film 13 so as to correspond to the plurality of sub-pixels. As shown in FIG. 3, the first electrodes 14 are connected to the drain electrodes of the TFTs 12 through contact holes formed in the planarizing film 13. The first electrodes 14 have a function to inject holes (positive holes) into the organic EL layers 16. In order to improve efficiency of hole injection into the organic EL layers 16, it is more preferable that the first electrodes 14 be made of a material with a high work function. Examples of the material of the first electrodes 14 include metal materials such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Other examples of the material of the first electrodes 14 include alloys such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al). Still other examples of the material of the first electrodes 14 include conductive oxides such as tin oxide (SnO), zinc oxide (ZnO), indium tin oxide (ITO), and indium zinc oxide (IZO), etc. The first electrodes 14 may have a multilayered structure comprised of layers of the above materials. Examples of the material with a high work function include indium tin oxide (ITO) and indium zinc oxide (IZO).

As shown in FIG. 3, the edge cover 15 is formed in a grid pattern so as to cover the peripheries of the first electrodes 14. Examples of the material of the edge cover 15 include inorganic films such as silicon oxide (SiO₂), silicon nitride (SiNₓ (x is a positive number)) like trisilicon tetranitride (Si₃N₄), and silicon oxynitride (SiNO), and organic films such as polyimide resin, acrylic resin, polysiloxane resin, and novolac resin.

As shown in FIG. 3, the plurality of organic EL layers 16 are arranged in a matrix on the first electrodes 14 so as to correspond to the plurality of sub-pixels. As shown in FIG. 4, the organic EL layer 16 includes a hole injection layer 1, a hole transport layer 2, a light emitting layer 3, an electron transport layer 4, and an electron injection layer 5 which are sequentially formed on the first electrode 14.

The hole injection layer 1 is also called an anode buffer layer and functions to make the energy levels of the first electrode 14 and the organic EL layer 16 close to each other to improve efficiency of hole injection from the first electrode 14 into the organic EL layer 16. Examples of the material of the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve efficiency of hole transport from the first electrode 14 to the organic EL layer 16. Examples of the material of the hole transport layer 2 include porphyrin derivatives, aromatic tertiary amine compounds, styrylamine derivatives, polyvinylcarbazole, poly-p-phenylene vinylene, polysilanes, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light emitting layer 3 is a region where holes and electrons injected from the first electrode 14 and the second electrode 17 when a voltage is applied by the first electrode 14 and the second electrode 17 recombine. The light emitting layer 3 is made of a material with high emission efficiency. Examples of the material of the light emitting layer 3 include metal oxinoid compounds (8-hydroxyquinoline metal complexes), naphthalene derivatives, anthracene derivatives, diphenylethylene derivatives, vinylacetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylene vinylene, and polysilanes.

The electron transport layer 4 functions to efficiently move electrons to the light emitting layer 3. Examples of the material of the electron transport layer 4 include organic compounds such as oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 functions to make the energy levels of the second electrode 17 and the organic EL layer 16 close to each other to improve efficiency of electron injection from the second electrode 17 into the organic EL layer 16. With this function, the drive voltage for the organic EL element 18 can be reduced. The electron injection layer 5 is also called a cathode buffer layer. Examples of the material of the electron injection layer 5 include inorganic alkaline compounds such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As shown in FIG. 3, the second electrode 17 covers the organic EL layers 16 and the edge cover 15 so as to serve as a common electrode for the plurality of sub-pixels. The second electrode 17 functions to inject electrons into the organic EL layers 16. In order to improve efficiency of electron injection into the organic EL layers 16, it is more preferable that the second electrode 17 be made of a material with a low work function. Examples of the material of the second electrode 17 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Other examples of the material of the second electrode 17 include alloys such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al). Still other examples of the material of the second electrode 17 include conductive oxides such as tin oxide (SnO), zinc oxide (ZnO), indium tin oxide (ITO), and indium zinc oxide (IZO). The second electrode 17 may have a multilayered structure comprised of layers of the above materials. Examples of the material with a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As shown in FIG. 1, the first weir wall Wa is formed so as to surround the display region D. As shown in FIG. 5, the first weir wall Wa is formed so as to contact a peripheral end R of an organic layer 20a, described later, of the sealing film 22a with a first inorganic layer 19a, described later, of the sealing film 22a interposed therebetween and to overlap the peripheral end R of the organic layer 20a. As shown in FIGS. 1, 2, and 5, in order to make a liquid organic resin material supplied by an inkjet method spread more slowly to form the organic layer 20a, a plurality of grooves C are formed next to each other in the upper surface of the first weir wall Wa so as to extend along the perimeter of the display region D. As shown in FIG. 5, the upper surface of the first weir wall Wa has a wave-like cross-section due to the plurality of grooves C. Although the first weir wall Wa having two grooves C is shown in FIGS. 1, 2, and 5, the number of grooves C is not limited to two. For example, the number of grooves C may be one or three or more. Although the frame-shaped grooves C are shown in the present embodiment, the grooves C may be formed in a non-continuous pattern along the perimeter of the display region D. For example, the grooves C have a width of about 1 micrometer to several tens of micrometers and a depth of about 0.5 μm to 1 μm. As shown in FIG. 3, the first weir wall Wa is formed by a planarizing layer 13a that is formed of the same material in the same layer as the planarizing film 13. Specifically, the first weir wall Wa can be formed by patterning a photosensitive organic resin material using a gray-tone mask or a halftone mask.

As shown in FIG. 1, the second weir wall Wb is formed so as to surround the first weir wall Wa. As shown in FIG. 5, the second weir wall Wb is formed so as to contact the peripheral end R of the organic layer 20a with the first inorganic layer 19a interposed therebetween and to overlap the edge of the peripheral end R of the organic layer 20a. As shown in FIG. 5, the second weir wall Wb is formed by an edge cover layer 15a that is formed of the same material in the same layer as the edge cover 15.

As shown in FIGS. 3 and 5, the sealing film 22a includes the first inorganic layer 19a formed so as to cover the organic EL element 18, the organic layer 20a formed on the first inorganic layer 19a, and a second inorganic layer 21a formed so as to cover the organic layer 20a.

The first inorganic layer 19a and the second inorganic layer 21a are made of, e.g., an inorganic insulating film such as a silicon nitride film, a silicon oxide film, or a silicon oxynitride film. The second inorganic layer 21a is preferably made of, e.g., a silicon nitride film having high barrier properties.

The organic layer 20a is made of, e.g., an organic resin material such as acrylate, polyurea, parylene, polyimide, or polyamide.

The organic EL display device 30a described above is flexible and is configured to display an image by emitting light as appropriate from the light emitting layers 3 of the organic EL layers 16 via the TFTs 12 at the sub-pixels.

Next, a method for manufacturing the organic EL display device 30a of the present embodiment will be described. The method for manufacturing the organic EL display device 30a of the present embodiment includes an organic EL element forming process and a sealing film forming process.

<Organic EL Element Forming Process>

A basecoat film 11, an organic EL element 18 (TFTs 12, a planarizing film 13, first electrodes 14, an edge cover 15, organic EL layers 16 (hole injection layers 1, hole transport layers 2, light emitting layers 3, electron transport layers 4, electron injection layers 5), a second electrode 17), a first weir wall Wa, and a second weir wall Wb are formed on the surface of a base substrate 10 made of, e.g., a polyimide resin by a well-known method. When forming the planarizing film 13, grooves C are formed in the upper surface of the first weir wall Wa in the frame region F by using, e.g., a gray-tone mask or a halftone mask, as described above.

<Sealing Film Forming Process>

First, a first inorganic layer 19a is formed by depositing an inorganic insulating film such as, e.g., a silicon nitride film with a thickness of about several tens of nanometers to several micrometers by a plasma chemical vapor deposition (CVD) method so as to cover the organic EL element 18 formed in the organic EL element forming process.

Next, an organic layer 20a is formed by injecting an organic resin material such as, e.g., acrylate with a thickness of about several micrometers to several tens of micrometers by an inkjet method on the entire surface of the substrate having the first inorganic layer 19a formed thereon.

Then, a second inorganic layer 21a is formed by depositing an organic insulating film such as, e.g., a silicon nitride film with a thickness of about several tens of nanometers to several micrometers by a plasma CVD method on the surface having the organic layer 20a formed thereon. A sealing film 22a comprised of the first inorganic layer 19a, the organic layer 20a, and the second inorganic layer 21a is thus formed.

The organic EL display device 30a of the present embodiment can be manufactured in this manner

As described above, the organic EL display device 30a of the present embodiment has the following effects (1) to (3).

(1) The groove C extending along the perimeter of the display region D is formed in the upper surface of the first weir wall Wa that overlaps the peripheral end R of the organic layer 20a of the sealing film 22a. Accordingly, the surface area of the upper surface of the first weir wall Wa can be increased due to the structure of the groove C. The organic resin material injected by the inkjet method therefore spreads more slowly over the substrate having the first weir wall Wa formed thereon when forming the organic layer 20a, and the peripheral end R of the organic layer 20a of the sealing film 22a can thus be accurately formed. Accordingly, the organic EL display device 30a can be designed to have a small distance between the first weir wall Wa and the second weir wall Wb, namely, to have a narrow frame region F. The peripheral end R of the organic layer 20a of the sealing film 22a can thus be accurately formed, and an organic EL display device with a narrower frame can be implemented.

(2) Since the plurality of grooves C are formed next to each other in the upper surface of the first weir wall Wa, the surface area of the upper surface of the first weir wall Wa can further be increased, and the organic resin material can be made to spread even more slowly to form the organic layer 20a.

(3) In the case where the second inorganic layer 21a is made of a silicon nitride film having high barrier properties, sealing performance of the sealing film 22a can be improved as the second inorganic layer 21a is formed so as to cover the organic layer 20a.

### Second Embodiment

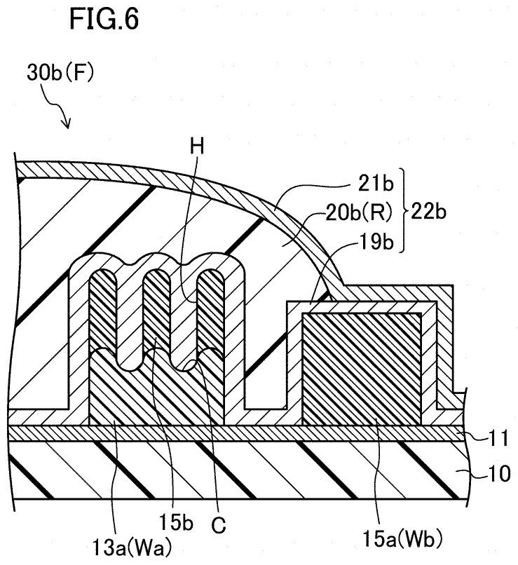

FIG. 6 shows a second embodiment of the display device according to the present invention. FIG. 6 is a sectional view showing a detailed configuration of a frame region F of an organic EL display device 30b of the present embodiment. In the following embodiments, the same portions as those in FIGS. 1 to 5 are denoted with the same reference characters as those in FIGS. 1 to 5, and detailed description thereof will be omitted.

Although the organic EL display device 30a having the first weir wall Wa made of the planarizing layer 13a is illustrated in the first embodiment, the organic EL display device 30b having a first weir wall Wa made of a planarizing layer 13a and an edge cover layer 15b is illustrated in the second embodiment.

As shown in FIG. 6, the organic EL display device 30b includes: a base substrate 10; an organic EL element 18 (see FIG. 2 etc.), a first weir wall Wa, and a second weir wall Wb which are formed on the base substrate 10 with a basecoat film 11 interposed therebetween; and a sealing film 22b formed so as to cover the organic EL element 18, the first weir wall Wa, and the second weir wall Wb. As in the organic EL display device 30a of the first embodiment, a rectangular display region D where an image is displayed is defined in the organic EL display device 30b, and a plurality of pixels are arranged in a matrix in the display region D.

As shown in FIG. 6, the first weir wall Wa is formed so as to contact a peripheral end R of an organic layer 20b, described later, of the sealing film 22b with a first inorganic layer 19b, described later, of the sealing film 22b interposed therebetween and to overlap the peripheral end R of the organic layer 20b. As shown in FIG. 6, the edge cover layer 15b is formed on the first weir wall Wa. As shown in FIG. 6, the edge cover layer 15b has a plurality of openings H formed so as to correspond to a plurality of grooves C. Each recess that is a combination of the groove C formed in the planarizing layer 13a and the opening H formed in the edge cover layer 15b and connecting to the groove C has, e.g., a width of about 1 micrometer to several tens of micrometers and a depth of about 0.5 μm to 1 μm. As shown in FIG. 6, the edge cover layer 15b formed of the same material in the same layer as the edge cover 15 is provided on the first weir wall Wa that is made of the planarizing layer 13a formed of the same material in the same layer as the planarizing film 13.

As shown in FIG. 6, the sealing film 22b includes the first inorganic layer 19b formed so as to cover the organic EL element 18, the organic layer 20b formed on the first inorganic layer 19b, and a second inorganic layer 21b formed so as to cover the organic layer 20b.

The first inorganic layer 19b and the second inorganic layer 21b are made of, e.g., an inorganic insulating film such as a silicon nitride film, a silicon oxide film, or a silicon oxynitride film. The second inorganic layer 21b is preferably made of, e.g., a silicon nitride film having high barrier properties.

The organic layer 20b is made of, e.g., an organic resin material such as acrylate, polyurea, parylene, polyimide, or polyamide.

The organic EL display device 30b described above is flexible and is configured to display an image by emitting light as appropriate from light emitting layers 3 of organic EL layers 16 via TFTs 12 at sub-pixels.

The organic EL display device 30b of the present embodiment can be manufactured by, e.g., changing the pattern shape for forming the edge cover 15 in the method for manufacturing the organic EL display device 30a described in the first embodiment.

As described above, the organic EL display device 30b of the present embodiment has the above effects (1) to (3) and the following effect (4).

The effect (1) will be described in detail. The groove C extending along the perimeter of the display region D is formed in the upper surface of the first weir wall Wa that overlaps the peripheral end R of the organic layer 20b of the sealing film 22b. Accordingly, the surface area of the upper surface of the first weir wall Wa can be increased due to the structure of the groove C. The organic resin material injected by an inkjet method therefore spreads more slowly over the substrate having the first weir wall Wa formed thereon when forming the organic layer 20b, and the peripheral end R of the organic layer 20b of the sealing film 22b can thus be accurately formed. Accordingly, the organic EL display device 30b can be designed to have a small distance between the first weir wall Wa and the second weir wall Wb, namely, to have a narrow frame region F. The peripheral end R of the organic layer 20b of the sealing film 22b can thus be accurately formed, and an organic EL display device with a narrower frame can be implemented.

The effect (2) will be described in detail. Since the plurality of grooves C are formed next to each other in the upper surface of the first weir wall Wa, the surface area of the upper surface of the first weir wall Wa can further be increased, and the organic resin material can be made to spread even more slowly to form the organic layer 20b.

The effect (3) will be described in detail. In the case where the second inorganic layer 21b is made of a silicon nitride film having high barrier properties, sealing performance of the sealing film 22b can be improved as the second inorganic layer 21b is formed so as to cover the organic layer 20b.

(4) The edge cover layer 15b made of the material of the edge cover 15 is formed on the first weir wall Wa, and the openings H are formed in the edge cover layer 15b so as to correspond to the grooves C. Accordingly, the surface area of the upper surface of the first weir wall Wa can be even further increased, and the organic resin material can be made to spread even more slowly to form the organic layer 20b.

### Third Embodiment

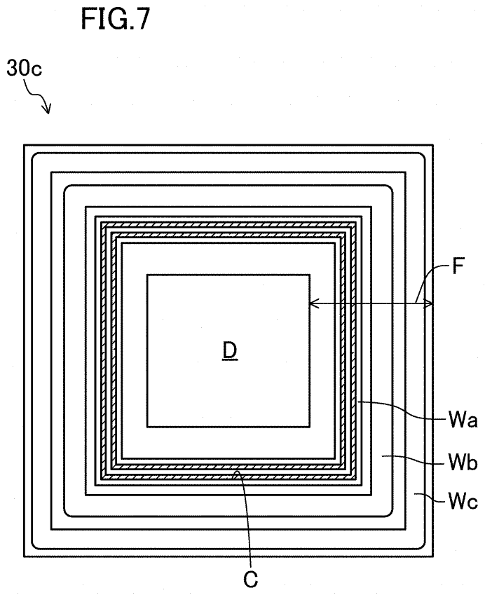

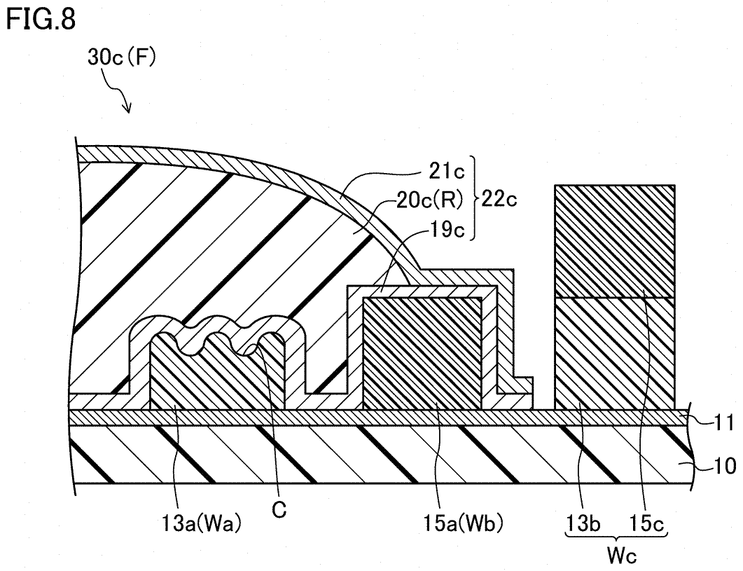

FIGS. 7 and 8 show a third embodiment of the display device according to the present invention. FIG. 7 is a plan view showing a schematic configuration of an organic EL display device 30c of the present embodiment. FIG. 8 is a sectional view showing a detailed configuration of a frame region F of the organic EL display device 30c.

Although the organic EL display devices 30a, 30b having the first weir wall Wa and the second weir wall Wb are illustrated in the first and second embodiments, the organic EL display device 30c having a first weir wall Wa, a second weir wall Wb, and a third weir wall Wc is illustrated in the third embodiment.

As shown in FIGS. 7 and 8, the organic EL display device 30c includes: a base substrate 10; an organic EL element 18 (see FIG. 2 etc.), a first weir wall Wa, a second weir wall Wb, and a third weir wall Wc which are formed on the base substrate 10 with a basecoat film 11 interposed therebetween; and a sealing film 22c formed so as to cover the organic EL element 18, the first weir wall Wa, and the second weir wall Wb. As in the organic EL display device 30a of the first embodiment, a rectangular display region D where an image is displayed is defined in the organic EL display device 30c, and a plurality of pixels are arranged in a matrix in the display region D.

As shown in FIG. 8, the first weir wall Wa is formed so as to contact a peripheral end R of an organic layer 20c, described later, of the sealing film 22c with a first inorganic layer 19c, described later, of the sealing film 22c interposed therebetween and to overlap the peripheral end R of the organic layer 20c.

As shown in FIG. 7, the third weir wall Wc is formed so as to surround the second weir wall Wb. As shown in FIG. 8, the third weir wall Wc includes a bottom layer 13b formed of the same material in the same layer as a planarizing film 13 and a top layer 15c formed of the same material in the same layer as an edge cover 15.

As shown in FIG. 8, the sealing film 22c includes the first inorganic layer 19c formed so as to cover the organic EL element 18, the organic layer 20c formed on the first inorganic layer 19c, and a second inorganic layer 21c formed so as to cover the organic layer 20c.

The first inorganic layer 19c and the second inorganic layer 21c are made of, e.g., an inorganic insulating film such as a silicon nitride film, a silicon oxide film, or a silicon oxynitride film. The second inorganic layer 21c is preferably made of, e.g., a silicon nitride film having high barrier properties.

The organic layer 20c is made of, e.g., an organic resin material such as acrylate, polyurea, parylene, polyimide, or polyamide.

The organic EL display device 30c described above is flexible and is configured to display an image by emitting light as appropriate from light emitting layers 3 of organic EL layers 16 via TFTs 12 at sub-pixels.

The organic EL display device 30c of the present embodiment can be manufactured by, e.g., changing the pattern shapes for forming the planarizing film 13 and the edge cover 15 in the method for manufacturing the organic EL display device 30a described in the first embodiment.

As described above, the organic EL display device 30c of the present embodiment has the above effects (1) to (3) and the following effect (5).

The effect (1) will be described in detail. The groove C extending along the perimeter of the display region D is formed in the upper surface of the first weir wall Wa that overlaps the peripheral end R of the organic layer 20c of the sealing film 22c. Accordingly, the surface area of the upper surface of the first weir wall Wa can be increased due to the structure of the groove C. The organic resin material injected by an inkjet method therefore spreads more slowly over the substrate having the first weir wall Wa formed thereon when forming the organic layer 20c, and the peripheral end R of the organic layer 20c of the sealing film 22c can thus be accurately formed. Accordingly, the organic EL display device 30c can be designed to have a small distance between the first weir wall Wa and the second weir wall Wb, namely, to have a narrow frame region F. The peripheral end R of the organic layer 20c of the sealing film 22c can thus be accurately formed, and an organic EL display device with a narrower frame can be implemented.

The effect (2) will be described in detail. Since the plurality of grooves C are formed next to each other in the upper surface of the first weir wall Wa, the surface area of the upper surface of the first weir wall Wa can further be increased, and the organic resin material can be made to spread even more slowly to form the organic layer 20c.

The effect (3) will be described in detail. In the case where the second inorganic layer 21c is made of a silicon nitride film having high barrier properties, sealing performance of the sealing film 22c can be improved as the second inorganic layer 21c is formed so as to cover the organic layer 20c.

(5) The third weir wall We including the bottom layer 13b made of the material of the planarizing film 13 and the top layer 15c made of the material of the edge cover 15 is formed in the frame region F so as to surround the second weir wall Wb. Accordingly, even when the organic resin material that will form the organic layer 20c of the sealing film 22c flows outward over the second weir wall Wb, the organic resin material can be restrained from spreading further outward.

Although the present embodiment is described with respect to the configuration in which the third weir wall Wc is added to the organic EL display device 30a of the first embodiment, the third weir wall Wc may be added to the organic EL display device 30b of the second embodiment.

### Fourth Embodiment

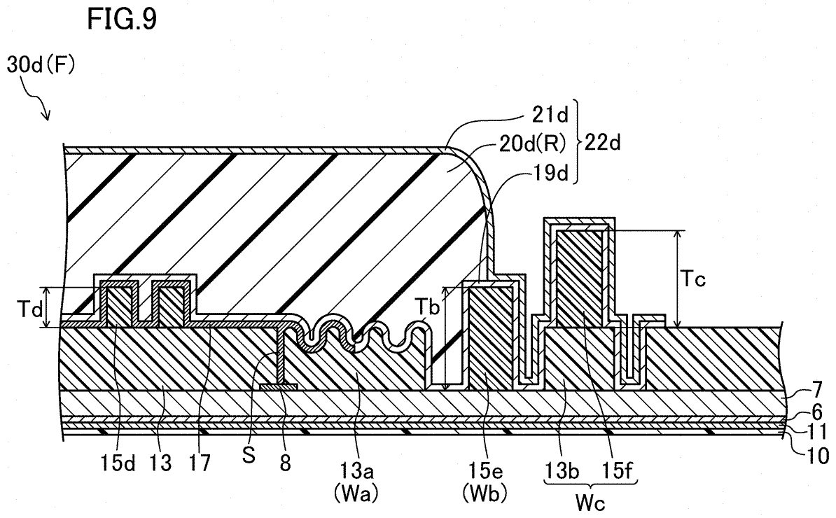

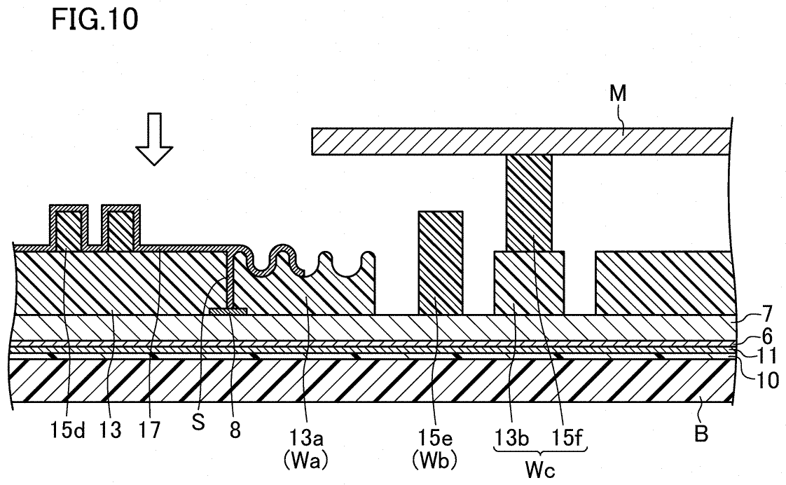

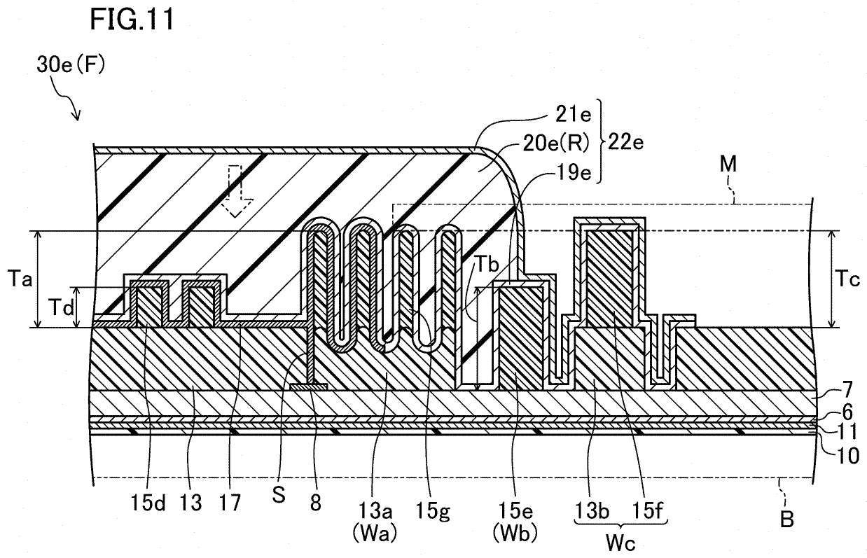

FIGS. 9 to 11 show a fourth embodiment of the display device according to the present invention. FIG. 9 is a sectional view showing a detailed configuration of a frame region F of an organic EL display device 30d of the present embodiment. FIG. 10 is a sectional view illustrating a method for manufacturing the organic EL display device 30d. FIG. 11 is a sectional view showing a detailed configuration of a frame region F of an organic EL display device 30e. The organic EL display device 30e is a modification of the organic EL display device 30d.

Although the organic EL display devices 30a to 30c in which the edge cover layer 15a forming the second weir wall Wb has the same thickness as the edge cover 15 in the display region D are illustrated in the first to third embodiments, an organic EL display device 30d etc. in which an edge cover layer 15e forming a second weir wall Wb is thicker than an edge cover 15 in a display region D is illustrated in the present embodiment.

As shown in FIG. 9, the organic EL display device 30d includes: a base substrate 10; an organic EL element 18 (see FIG. 2 etc.), a first weir wall Wa, a second weir wall Wb, and a third weir wall Wc which are formed on the base substrate 10 with a basecoat film 11 interposed therebetween; and a sealing film 22d formed so as to cover the organic EL element 18, the first weir wall Wa, and the second weir wall Wb. As in the organic EL display device 30a of the first embodiment, a rectangular display region D where an image is displayed is defined in the organic EL display device 30d, and a plurality of pixels are arranged in a matrix in the display region D.

As shown in FIG. 9, in the organic EL display device 30d, a gate insulating film 6 and an interlayer insulating film 7 which form TFTs 12 are sequentially formed between the basecoat film 11 and a planarizing film 13.

As shown in FIG. 9, a wiring 8 is formed between the interlayer insulating film 7 and the planarizing film 13 in the frame region F of the organic EL display device 30d. As shown in FIG. 9, a slit S extending through the planarizing film 13 in the thickness direction is formed between the planarizing film 13 and the first weir wall Wa in the frame region F of the organic EL display device 30d so that the slit S separates the planarizing film 13 from the first weir wall Wa. As shown in FIG. 9, in the frame region F of the organic EL display device 30d, a second electrode 17 serving as a cathode has its end connected to the wiring 8 through the slit S.

As shown in FIG. 9, a dummy edge cover 15d is formed on the planarizing film 13 in the frame region F of the organic EL display device 30d. The dummy edge cover 15d is formed of the same material in the same layer as the edge cover 15 in the display region D, and the thickness Td of the dummy edge cover 15d is the same as that of the edge cover 15.

As shown in FIG. 9, the first weir wall Wa is formed so as to contact a peripheral end R of an organic layer 20d, described later, of the sealing film 22d with a first inorganic layer 19d, described later, of the sealing film 22d interposed therebetween and to overlap the peripheral end R of the organic layer 20d.

As shown in FIG. 9, the second weir wall Wb is formed so as to surround the first weir wall Wa. As shown in FIG. 9, the second weir wall Wb is formed so as to contact the peripheral end R of the organic layer 20d with the first inorganic layer 19d interposed therebetween and to overlap the edge of the peripheral end R of the organic layer 20d. As shown in FIG. 9, the second weir wall Wb is formed by an edge cover layer 15e that is formed of the same material in the same layer as the edge cover 15. As shown in FIG. 9, the thickness Tb of the edge cover layer 15e is larger than the thickness Td of the dummy edge cover 15d.

As shown in FIG. 9, the third weir wall Wc is formed so as to surround the second weir wall Wb. As shown in FIG. 9, the third weir wall Wc includes a bottom layer 13b formed of the same material in the same layer as the planarizing film 13 and a top layer 15f formed of the same material in the same layer as the edge cover 15. As shown in FIG. 9, the thickness Tc of the top layer 15f is the same as the thickness Tb of the edge cover layer 15e and is larger than the thickness Td of the dummy edge cover 15d.

As shown in FIG. 9, the sealing film 22d includes the first inorganic layer 19d formed so as to cover the organic EL element 18, the organic layer 20d formed on the first inorganic layer 19d, and a second inorganic layer 21d formed so as to cover the organic layer 20d.

The first inorganic layer 19d and the second inorganic layer 21d are made of, e.g., an inorganic insulating film such as a silicon nitride film, a silicon oxide film, or a silicon oxynitride film. The second inorganic layer 21d is preferably made of, e.g., a silicon nitride film having high barrier properties.

The organic layer 20d is made of, e.g., an organic resin material such as acrylate, polyurea, parylene, polyimide, or polyamide.

The organic EL display device 30d described above is flexible and is configured to display an image by emitting light as appropriate from light emitting layers 3 of organic EL layers 16 via the TFTs 12 at sub-pixels.

The organic EL display device 30d of the present embodiment can be manufactured by, e.g., changing the pattern shapes for forming the planarizing film 13 and the edge cover 15 in the method for manufacturing the organic EL display device 30a described in the first embodiment. As shown in FIG. 10, in the method for manufacturing the organic EL display device 30d, the layers from the base substrate 10 to the edge cover 15 are sequentially formed on a support film B, and vapor deposition is then performed using a frame-shaped deposition mask M placed in contact with the surface of the third weir wall Wc. The second electrode 17 can be formed in this manner.

Although the organic EL display device 30d that is a modification of the organic EL display device 30c of the third embodiment is illustrated in the present embodiment, the present invention may be an organic EL display device 30e that is a combination of the organic EL display device 30d of the fourth embodiment and the organic EL display device 30b of the second embodiment.

As shown in FIG. 11, the organic EL display device 30e includes: a base substrate 10; an organic EL element 18 (see FIG. 2 etc.), a first weir wall Wa, a second weir wall Wb, and a third weir wall Wc which are formed on the base substrate 10 with a basecoat film 11 interposed therebetween; and a sealing film 22e formed so as to cover the organic EL element 18, the first weir wall Wa, and the second weir wall Wb.

As shown in FIG. 11, the first weir wall Wa is formed so as to contact a peripheral end R of an organic layer 20e, described later, of the sealing film 22e with a first inorganic layer 19e, described later, of the sealing film 22e interposed therebetween and to overlap the peripheral end R of the organic layer 20e. As shown in FIG. 11, an edge cover layer 15g is formed on the first weir wall Wa. The edge cover layer 15g has a plurality of openings H formed so as to correspond to a plurality of grooves C. The edge cover layer 15g is formed of the same material in the same layer as the edge cover 15. As shown in FIG. 11, the thickness Ta of the edge cover layer 15g is larger than the thickness Td of the dummy edge cover 15d.

As shown in FIG. 11, the second weir wall Wb is formed so as to surround the first weir wall Wa. As shown in FIG. 11, the second weir wall Wb is formed so as to contact the peripheral end R of the organic layer 20e with the first inorganic layer 19e interposed therebetween and to overlap the edge of the peripheral end R of the organic layer 20e. As shown in FIG. 11, the second weir wall Wb is formed by the edge cover layer 15e that is formed of the same material in the same layer as the edge cover 15.

As shown in FIG. 11, the third weir wall Wc is formed so as to surround the second weir wall Wb. As shown in FIG. 11, the third weir wall Wc includes a bottom layer 13b formed of the same material in the same layer as the planarizing film 13 and a top layer 15f formed of the same material in the same layer as the edge cover 15. As shown in FIG. 11, since the thickness Tc of the top layer 15f is the same as the thickness Ta of the edge cover layer 15g, the height of the top layer 15f is the same as that of the edge cover layer 15g.

As shown in FIG. 11, the sealing film 22e includes the first inorganic layer 19e formed so as to cover the organic EL element 18, the organic layer 20e formed on the first inorganic layer 19e, and a second inorganic layer 21e formed so as to cover the organic layer 20e.

The first inorganic layer 19e and the second inorganic layer 21e are made of, e.g., an inorganic insulating film such as a silicon nitride film, a silicon oxide film, or a silicon oxynitride film. The second inorganic layer 21e is preferably made of, e.g., a silicon nitride film having high barrier properties.

The organic layer 20e is made of, e.g., an organic resin material such as acrylate, polyurea, parylene, polyimide, or polyamide.

The organic EL display device 30e described above is flexible and is configured to display an image by emitting light as appropriate from light emitting layers 3 of organic EL layers 16 via TFTs 12 at sub-pixels. The organic EL display device 30e can be manufactured in a manner similar to that of the organic EL display device 30d described above (see long dashed double short dashed line in FIG. 11).

As described above, the organic EL display device 30d (30e) of the present embodiment has the above effects (1) to (5) and the following effects (6) to (8).

The effect (1) will be described in detail. The groove C extending along the perimeter of the display region D is formed in the upper surface of the first weir wall Wa that overlaps the peripheral end R of the organic layer 20d (20e) of the sealing film 22d (22e). Accordingly, the surface area of the upper surface of the first weir wall Wa can be increased due to the structure of the groove C. The organic resin material injected by an inkjet method therefore spreads more slowly over the substrate having the first weir wall Wa formed thereon when forming the organic layer 20d (20e), and the peripheral end R of the organic layer 20d (20e) of the sealing film 22d (22e) can thus be accurately formed. Accordingly, the organic EL display device 30d (30e) can be designed to have a small distance between the first weir wall Wa and the second weir wall Wb, namely, to have a narrow frame region F. The peripheral end R of the organic layer 20d (20e) of the sealing film 22d (22e) can thus be accurately formed, and an organic EL display device with a narrower frame can be implemented.

The effect (2) will be described in detail. Since the plurality of grooves C are formed next to each other in the upper surface of the first weir wall Wa, the surface area of the upper surface of the first weir wall Wa can further be increased, and the organic resin material can be made to spread even more slowly to form the organic layer 20d (20e).

The effect (3) will be described in detail. In the case where the second inorganic layer 21d (21e) is made of a silicon nitride film having high barrier properties, sealing performance of the sealing film 22d (22e) can be improved as the second inorganic layer 21d (21e) is formed so as to cover the organic layer 20d (20e).

The effect (4) will be described in detail. In the organic EL display device 30e, the edge cover layer 15g made of the material of the edge cover 15 is formed on the first weir wall Wa, and the openings H are formed in the edge cover layer 15g so as to correspond to the grooves C. Accordingly, the surface area of the upper surface of the first weir wall Wa can be even further increased, and the organic resin material can be made to spread even more slowly to form the organic layer 20e.

The effect (5) will be described in detail. The third weir wall Wc including the bottom layer 13b made of the material of the planarizing film 13 and the top layer 15f made of the material of the edge cover 15 is formed in the frame region F so as to surround the second weir wall Wb. Accordingly, even when the organic resin material that will form the organic layer 20d (20e) of the sealing film 22d (22e) flows outward over the second weir wall Wb, the organic resin material can be restrained from spreading further outward.

(6) The slit S extending through the planarizing film 13 in the thickness direction is formed between the planarizing film 13 and the first weir wall Wa, and the second electrode 17 is connected to the wiring 8 through the slit S. The second electrode 17 and the wiring 8 can thus be connected using the slit S that separates the planarizing film 13 from the first weir wall Wa.

(7) The second electrode 17 is formed by performing vapor deposition using the deposition mask M placed in contact with the surface of the third weir wall Wc of the organic EL display device 30d and with the surfaces of the first weir wall Wa (the edge cover layer 15g on the first weir wall Wa) and the third weir wall Wc of the organic EL display device 30e. Accordingly, the second electrode 17 can be formed at a predetermined position even if the deposition mask M is aligned with low accuracy.

(8) The edge cover layer 15e and the top layer 15f of the organic EL display device 30d are thicker than the edge cover 15 in the display region D. Accordingly, the surface area of the second weir wall Wb and the third weir wall Wc can further be increased, and the organic resin material can be made to spread even more slowly to form the organic layer 20d. The edge cover layer 15g, the edge cover layer 15e, and the top layer 15f of the organic EL display device 30e are thicker than the edge cover 15 in the display region D. Accordingly, the surface area of the upper surface of the first weir wall Wa and the surface area of the second weir wall Wb and the third weir wall We can be even further increased, and the organic resin material can be made to spread even more slowly to form the organic layer 20e.

### OTHER EMBODIMENTS

The above embodiments are described with respect to the organic EL layers having a five-layered structure comprised of the hole injection layer, the hole transport layer, the light emitting layer, the electron transport layer, and the electron injection layer. However, the organic EL layers may have, e.g., a three-layered structure comprised of a layer serving as both a hole injection layer and a hole transport layer, a light emitting layer, and a layer serving as both an electron transport layer and an electron injection layer.

The above embodiments are described with respect to the organic EL display device in which the first electrodes serve as an anode and the second electrode serves as a cathode. However, the present invention is also applicable to organic EL display devices in which the organic EL layers have an inverted multilayered structure, namely organic EL display devices in which the first electrodes serve as a cathode and the second electrode serves as an anode.

The above embodiments are described with respect to the organic EL display device that includes an element substrate using those electrodes of the TFTs which are connected to the first electrodes as drain electrodes. However, the present invention is also applicable to organic EL display devices that include an element substrate using those electrodes of the TFTs which are connected to the first electrodes as source electrodes.

The above embodiments are described with respect to the organic EL display device as an example of a display device. However, the present invention is also applicable to display devices including a plurality of current-driven light emitting elements. For example, the present invention is applicable to display devices including quantum-dot light emitting diodes (QLEDs), namely light emitting elements using a quantum-dot containing layer.

### INDUSTRIAL APPLICABILITY

As described above, the present invention is useful for flexible display devices.

### DESCRIPTION OF REFERENCE CHARACTERS

C Groove
D Display Region
F Frame Region
H Opening
R Peripheral End
S Slit
Wa First Weir Wall
Wb Second Weir Wall
We Third Weir Wall
8 Wiring
10 Base Substrate
12 TFT (Switching Element)
13 Planarizing Film
13b Bottom Layer
14 First Electrode
15 Edge Cover
15b, 15g Edge Cover Layer
15c, 15f Top Layer
16 Organic EL Layer (Light Emitting Layer)
17 Second Electrode (Cathode)
18 Organic EL Element (Light Emitting Element)
19a to 19e First Inorganic Layer
20a to 20e Organic Layer
21a to 21e Second Inorganic Layer
22a to 22e Sealing Film
30a to 30e Organic EL Display Device

1: A display device which includes a base substrate, a plurality of switching elements provided on the base substrate, a planarizing film formed on the plurality of switching elements to flatten a surface having the plurality of switching elements formed thereon, a light emitting element provided on the planarizing film and including an edge cover, and a sealing film formed so as to cover the light emitting element and formed by sequentially stacking a first inorganic layer, an organic layer, and a second inorganic layer, and in which a display region where an image is displayed and a frame region surrounding the display region are defined, characterized in that
a first weir wall and a second weir wall are formed in the frame region, the first weir wall being made of a material of the planarizing film and being formed so as to surround the display region and to overlap a peripheral end of the organic layer, and the second weir wall being made of a material of the edge cover and being formed so as to surround the first weir wall and to overlap an edge of the peripheral end of the organic layer, and
the first weir wall has a groove formed in its upper surface so as to extend along a perimeter of the display region.

2: The display device of claim 1, characterized in that
the light emitting element includes a plurality of first electrodes, a plurality of light emitting layers formed so as to correspond to the plurality of first electrodes, and a second electrode that is common to the plurality of light emitting layers, the plurality of first electrodes, the plurality of light emitting layers, and the second electrode being provided in this order from the base substrate side,
a wiring is formed on the base substrate side of the planarizing film,
a slit extending through the planarizing film in a thickness direction is formed between the planarizing film and the first weir wall, and
the second electrode is connected to the wiring through the slit.

3: The display device of claim 1, characterized in that
an edge cover layer made of the material of the edge cover is formed on the first weir wall, and
the edge cover layer has an opening formed so as to correspond to the groove.

4: The display device of claim 3, characterized in that the edge cover layer is thicker than the edge cover.

5: The display device of claim 1, characterized in that
a third weir wall is formed in the frame region so as to surround the second weir wall, the third weir wall including a bottom layer made of the material of the planarizing film and a top layer made of the material of the edge cover.

6: The display device of claim 5, characterized in that
the top layer is thicker than the edge cover.

7: The display device of claim 6, characterized in that
an edge cover layer made of the material of the edge cover is formed on the first weir wall,
the edge cover layer has an opening formed so as to correspond to the groove, and
the edge cover layer has the same height as the top layer.

8: The display device of claim 1, characterized in that
a plurality of the grooves are formed next to each other.

9: The display device of claim 1, characterized in that
the second inorganic layer is formed so as to cover the organic layer.

10: The display device of claim 1, characterized in that
the light emitting element is an organic electroluminescence element.

11: The display device of claim 1, characterized in that
the base substrate is flexible.
